(19) United States
(12) Patent Application Publication
(10) Pub. No.: US 2023/0378889 A1
(43) Pub. Date: Nov. 23, 2023

(54) INTERFEROMETERS HAVING AN AMPLIFIED PIEZOELECTRIC ACTUATOR AND SYSTEMS THEREOF

(71) Applicant: N-Sense, Inc., Ames, IA (US)

(72) Inventor: David Laird, Ames, IA (US)

(21) Appl. No.: 18/199,644

(22) Filed: May 19, 2023

Related U.S. Application Data
(60) Provisional application No. 63/344,527, filed on May 20, 2022.

(51) Int. Cl. H02N 2/04; H10N 30/20; G01B 9/02017

(52) U.S. Cl. CPC H02N 2/043; H10N 30/20; G01B 9/02021

(57) ABSTRACT

The present disclosure relates to an interferometer having an amplified piezoelectric actuator configured to move an optical component. Such an interferometer can be optimized for use in any region of the electromagnetic spectrum and can be used with various applications such as, but not limited to, spectroscopy.

### CROSS-REFERENCE TO RELATED APPLICATION

This application claims the benefit of U.S. Provisional Patent Application No. 63/344,527, filed on May 20, 2022, which is incorporated by reference herein in its entirety.

### FIELD

The present disclosure relates to an interferometer having an amplified piezoelectric actuator configured to move an optical component. Such an interferometer can be optimized for use in any region of the electromagnetic spectrum and can be used with various applications such as, but not limited to, spectroscopy.

### BACKGROUND

Interferometers are critical components of modern spectrometers and many other analytical instruments. The placement and exact position of optical components within an interferometer can impact its resolution and use.

### SUMMARY

The present disclosure relates to an interferometer for use in spectrometers and other applications that can use an amplified piezoelectric actuator to drive one or more moving reflectors, thereby obviating the need for a secondary laser-based optical system to measure the position of the moving reflector(s) during operation. In one embodiment, the position of the moving reflector(s) is determined from the driving voltage applied to the amplified piezoelectric actuator. In another embodiment, the position is determined by use of an associated gauge (e.g., a strain gauge, a capacitance gauge, or other gauge) capable of sensing the physical movement of the amplified piezoelectric actuator.

In a first aspect, the present disclosure encompasses an interferometer including: one or more optical components configured to receive and/or transmit light; and a first amplified piezoelectric actuator directly or indirectly coupled to at least one optical component.

In some embodiments, the first amplified piezoelectric actuator is configured to move at least one optical component. In particular embodiments, a position of at least one optical component is precisely controlled by the first amplified piezoelectric actuator. The position of the moving optical component(s) can be determined in any useful manner. In one instance, the position is determined by a voltage being applied to the first amplified piezoelectric actuator. In another instance, the position is determined by a sensing gauge associated with the first amplified piezoelectric actuator.

In some embodiments, the one or more optical components include: an optical source configured to generate light; a first reflector; a second reflector; a beamsplitter; and/or a target. In particular embodiments, the beamsplitter is configured to receive the light, to split the light into a first beam directed to the first reflector and into a second beam directed to the second reflector, and to receive the first and second beams transmitted from the first and second reflectors, thereby providing a combined beam. In further embodiments, the first amplified piezoelectric actuator is directly or indirectly coupled to the second reflector, and/or the first amplified piezoelectric actuator is configured to translate the second reflector away from or towards the beamsplitter. In other embodiments, the target is configured to receive the combined beam from the beamsplitter.

In some embodiments, the target includes a detector, a screen, or a camera. In other embodiments, the target includes the detector. In some embodiments, the detector includes an infrared detector, a mid-infrared detector, or a near-infrared detector. Additional targets and detectors are described herein.

In some embodiments, the first amplified piezoelectric actuator includes an amplified piezoelectric actuator configured to provide a translational movement of the second reflector from about 0.3 mm to about 5 mm.

In some embodiments, the first amplified piezoelectric actuator is configured for operation in an open-loop manner. In further embodiments, the interferometer includes a low noise circuit configured to provide one or more output voltages to drive the first amplified piezoelectric actuator, wherein the one or more output voltages are configured to provide a position of the second reflector.

In other embodiments, the first amplified piezoelectric actuator is configured for operation in a closed-looped manner. In further embodiments, the interferometer includes a sensing gauge (e.g., a strain gauge or a capacitance gauge) configured to determine a position of the second reflector, and the sensing gauge is configured to be associated with the amplified piezoelectric actuator. In yet other embodiments, the interferometer includes a circuit configured to employ a signal from the sensing gauge as an input signal for the circuit.

In further embodiments, the interferometer includes: a controller coupled to the first amplified piezoelectric actuator. In some embodiments, the controller is configured to directly or indirectly transmit a driving signal (e.g., a driving voltage) to the first amplified piezoelectric actuator and to optionally receive a signal from a sensing gauge. In other embodiments, the controller is configured to power and control the first amplified piezoelectric actuator.

In some embodiments, the first reflector is stationary. In other embodiments, the first reflector is moving.

In some embodiments, the first reflector is directly or indirectly coupled to the first amplified piezoelectric actuator or a second amplified piezoelectric actuator. For instance, the first or second amplified piezoelectric actuator can be configured to translate the first reflector away from and towards the beamsplitter. In another instance, the first reflector can move in a different direction from the second reflector, relative to the beamsplitter.

In any embodiment herein, the interferometer can further include: a return assembly configured to provide a supplemental pull force for the second reflector. In some embodiments, the return assembly is configured to supplement a maximum pull force of the amplified piezoelectric actuator. In some embodiments, a magnitude of the supplemental pull force is configured to equalize or to supplement a maximum push force and a maximum pull force of the amplified piezoelectric actuator.

In other embodiments, the first amplified piezoelectric actuator is configured to translate the second reflector away from and towards the beamsplitter, and the return assembly is configured to translate the second reflector away from the beamsplitter.

In yet other embodiments, the return assembly includes a spring coupled to the second reflector, and the spring is compressed or stretched upon translating the second reflector by the first amplified piezoelectric actuator in a forward stroke. In some embodiments, such compression and stretching thereby allows the spring to provide the supplemental pull force that translates the second reflector in the opposite direction on a back stroke.

In any embodiment herein, the interferometer can further include: one or more guide assemblies configured to align the first reflector and/or the second reflector when translating away from or towards the beamsplitter. In particular embodiments, the one or more guide assemblies include one or more bearings, sleeve bearings, guide bearings, or magnetic bearings located in proximity to the first or second reflector; and the one or more guide assemblies are configured to align the first or second reflector along an intended axis of motion that is towards and away from the beamsplitter.

In any embodiment herein, the interferometer can further include: an arm assembly including a surface, a pivot point, and a first outer edge. In some embodiments, the first and second reflectors are attached to the arm assembly. In other embodiments, a portion of the first outer edge of the arm assembly is directly or indirectly coupled to the first amplified piezoelectric actuator with a flexure, bearing, or other. In yet other embodiments, the first amplified piezoelectric actuator is configured to move the arm assembly about the pivot point, thereby moving the first and second reflectors, independently, away from or towards the beamsplitter.

In any embodiment herein, the interferometer can further include: a return assembly that is directly or indirectly coupled to the arm assembly. In some embodiments, the return assembly is configured to provide a force that moves the arm assembly in an opposite direction than a movement provided in a forward stroke by the first amplified piezoelectric actuator. In particular embodiments, the force provided by the return assembly occurs after the movement provided by the forward stroke.

In other embodiments, the arm assembly includes a second outer edge that is perpendicular to the first outer edge. In particular embodiments, a portion of the first outer edge or the second outer edge is directly or indirectly coupled to a return assembly configured to provide a force. In one instance, the force is configured to move the arm assembly in an opposite direction than a movement provided by the first amplified piezoelectric actuator.

In yet other embodiments, the arm assembly includes a first portion and a second portion, and the first and second portions extend away from the pivot point. In further embodiments, the first reflector is attached to the first portion, and the second reflector is attached to the second portion.

In any embodiment herein, the first reflector and/or the second reflector is independently selected from a mirror, a prism, a retroreflector, a retroreflector mirror, a retroreflector prism, or a corner cube retroreflector.

In any embodiment herein, the beamsplitter includes a plate beamsplitter or a cubic beamsplitter.

In any embodiment herein, the interferometer further includes: a compensating plate in an optical path between the beamsplitter and the first reflector.

In any embodiment herein, the interferometer further includes: an assembly (e.g., a mechanical assembly) configured to insert and retract a reference material into and out of an optical path.

In any embodiment herein, the interferometer further includes: a sample holder configured to provide a sample. In some embodiments, the sample holder is configured to interact the combined light beam with the sample, thereby providing an interacted light beam. In further embodiments, a detector is configured to receive the interacted light beam.

In any embodiment herein, the interferometer, the sample holder, and/or the detector are configured for measuring spectra of the sample using attenuated total internal reflectance (ATR), diffusion reflectance, photoacoustic, or transmission mode.

In any embodiment herein, the interferometer further includes: an ATR crystal substrate or an optically clear sample container or window against which a sample is pressed.

In any embodiment herein, the interferometer further includes: one or more flat mirrors, parabolic mirrors, off-axis parabolic mirrors, lenses, windows, or combinations thereof.

In any embodiment herein, the interferometer further includes one or more of the following:
one or more controller systems configured to power and/or control a component of the interferometer (e.g., an optical source, a first amplified piezoelectric actuator, and/or a detector);
one or more positioning systems configured to determine a position of the first reflector and/or the second reflector (e.g., based on a voltage driving the first amplified piezoelectric actuator and/or based on a signal from a sensing gauge configured to sense a movement) and/or a position of the first amplified piezoelectric actuator;
a first converter configured to digitize a signal transmitted from the detector;
a second converter configured to transform a digital signal transmitted from the one or more controller systems into an analog signal for driving the first amplified piezoelectric actuator;
a processor configured to receive one or more signals from the first amplified piezoelectric actuator, one or more sensing gauges, converter, and/or the detector (e.g., wherein the processor is optionally configured to record position data from the first amplified piezoelectric actuator, to record a signal from the detector, to generate an interferogram, to correct an interferogram for non-linearity and/or hysteresis between the forward and back strokes of the first amplified piezoelectric actuator, to generate an average interferogram, and/or to execute software for system control, data acquisition, data correction, data manipulation, and/or analysis including Fourier Transform of the interferogram to generate spectra);
a memory device capable of communicating with the processor (e.g., wherein the memory device is configured to store data, one or more outputs of the processor, and/or software programming); and/or
a display configured to display one or more outputs of the processor and/or the memory device (e.g., wherein the one or more outputs can include position data from the first amplified piezoelectric actuator, interferograms, Fourier Transform of the interferograms, and/or spectra).

In a second aspect, the present disclosure encompasses a system including: an interferometer (e.g., any described herein); and one or more controller systems configured to power and/or control a component of the interferometer (e.g., an optical source, a first amplified piezoelectric actuator, and/or a detector).

In some embodiments, the system further includes: one or more positioning systems configured to determine a position of the first reflector and/or the second reflector. In particular embodiments, the position is determined based on a voltage driving the first amplified piezoelectric actuator. In other embodiments, the position is determined based on a signal from a sensing gauge configured to sense a movement and/or a position of the first amplified piezoelectric actuator. In some embodiments, the one or more positioning systems are configured to determine a position of the first amplified piezoelectric actuator. In some embodiments, the one or more positioning systems can be configured to provide position data regarding the forward and backwards strokes of the amplified piezoelectric actuator.

In some embodiments, the system further includes: a first converter configured to digitize a signal transmitted from the detector.

In some embodiments, the system further includes: a second converter configured to transform a digital signal transmitted from the one or more controller systems into an analog signal for driving the first amplified piezoelectric actuator.

In other embodiments, the system further includes: a processor configured to receive one or more signals from a component of the interferometer (e.g., the first amplified piezoelectric actuator, one or more sensing gauges, converter, and/or the detector). In particular embodiments, the processor is configured to record position data from the first amplified piezoelectric actuator, to record a signal from the detector to generate an interferogram, to correct an interferogram for non-linearity and/or hysteresis between forward and back strokes of the first amplified piezoelectric actuator, to generate an average interferogram, and/or to execute software for system control, data acquisition, data correction, data manipulation, and/or analysis including Fourier Transform of the interferogram to generate spectra.

In some embodiments, the software can include one or more operations to correct one or more recorded interferograms for any non-linearity of and/or for any hysteresis between the forward and back strokes of the amplified piezoelectric actuator. In some embodiments, the software can include one or more operations to combine a plurality of interferograms that are generated during one or more forward and one or more back strokes of the amplified piezoelectric actuator to generate an average interferogram (e.g., before the Fourier Transform of the average interferogram is performed).

In some embodiments, the system further includes: a memory device capable of communicating with the processor. In particular embodiments, the memory device is configured to store data, one or more outputs of the processor, and/or software programming.

In some embodiments, the system further includes: a display configured to display one or more outputs of the processor and/or the memory device. In particular embodiments, the one or more outputs can include position data from the first amplified piezoelectric actuator, interferograms, Fourier Transform of the interferograms, and/or spectra.

In some embodiments, the system further includes: an internal reference standard configured to determine alignment of one or more components within an optical path of the interferometer and/or to calibrate a spectrum obtained by the interferometer. In some embodiments, the reference standard can include a reference material, which in turn can be disposed on or otherwise coupled to an assembly (e.g., a mechanical assembly) for inserting and retracting the reference material into and out of an optical path. In particular embodiments, the assembly can include a stationary base (e.g., any described herein) that provides a path for travel, as well as a mobile component (e.g., any described herein) that moves along the path. In some embodiments, the reference material can be disposed on or otherwise coupled to the stationary base.

In some embodiments, the system can further include one or more controller systems configured to power and/or control the assembly coupled to the reference standard. In particular embodiments, the one or more controller systems can be configured to directly or indirectly transmit a signal to the assembly (e.g., transmit a signal to the mobile component or a motor or actuator coupled to the mobile component), thereby moving the reference standard into or out of an optical path.

In a third aspect, the present disclosure encompasses a method of analyzing a sample. In some embodiments, the method includes: providing a sample in an optical path of a beam from an interferometer (e.g., any described herein); moving at least one optical component of the interferometer by using a first amplified piezoelectric actuator that is directly or indirectly coupled to the at least one optical component; and obtaining an interferogram of the sample from the interferometer.

In some embodiments, a position of the at least one optical component is determined by the first amplified piezoelectric actuator (e.g., any described herein).

In other embodiments, the method further includes (e.g., after said obtaining): processing the interferogram by way of Fourier Transform analysis. Additional details follow.

All publications, patents, and patent applications mentioned in this specification are herein incorporated by reference to the same extent as if each individual publication, patent, patent application, or item of information was specifically and individually indicated to be incorporated by reference. To the extent publications, patents, patent applications, and items of information incorporated by reference contradict the disclosure contained in the specification, the specification is intended to supersede and/or take precedence over any such contradictory material.

Where values are described in terms of ranges, it should be understood that the description includes the disclosure of all possible sub-ranges within such ranges, as well as specific numerical values that fall within such ranges irrespective of whether a specific numerical value or specific sub-range is expressly stated. The term “about” is meant to modify each recited numerical value within the range and sub-ranges.

The term “each,” when used in reference to a collection of items, is intended to identify an individual item in the collection but does not necessarily refer to every item in the collection, unless expressly stated otherwise, or unless the context of the usage clearly indicates otherwise.

Various embodiments of the features of this disclosure are described herein. However, it should be understood that such embodiments are provided merely by way of example, and numerous variations, changes, and substitutions can occur to those skilled in the art without departing from the scope of this disclosure. It should also be understood that various alternatives to the specific embodiments described herein are also within the scope of this disclosure.

### BRIEF DESCRIPTION OF THE DRAWINGS

The following drawings illustrate certain embodiments of the features and advantages of this disclosure. These embodiments are not intended to limit the scope of the appended claims in any manner. Like reference symbols in the drawings indicate like elements.

FIG. 1A-1B shows non-limiting schematics of exemplary interferometers. Provided are (A) a non-limiting interferometer 100 having a first amplified piezoelectric actuator 130; and (B) another non-limiting interferometer 1000 having a first amplified piezoelectric actuator 1030 and an optional second amplified piezoelectric actuator 1032.

FIG. 2A-2B shows further non-limiting schematics of exemplary interferometers. Provided are (A) a non-limiting interferometer 200 having a third reflector M3 205; and (B) another non-limiting interferometer 2000 having a third reflector M3 2005, as well as a beamsplitter 2002 coupled to a matching compensating plate 2003.

FIG. 3A-3B shows non-limiting schematics of exemplary interferometers. Provided are (A) a non-limiting interferometer 300 having an arm assembly 370, which in turn includes a first arm 370A and a second arm 370B; and (B) another non-limiting interferometer 3000 having an arm assembly 3070, which in turn includes a first arm 3070A, a second arm 3070B, and a third arm 3070C.

FIG. 4 shows a non-limiting schematic of an exemplary interferometer. Provided is a non-limiting interferometer 400 having an arm assembly 470 and a third reflector M3 405.

FIG. 5 shows a non-limiting schematic of an interferometer described in Example 1.

FIG. 6 shows a non-limiting schematic of an interferometer described in Example 2.

### DETAILED DESCRIPTION

The present disclosure relates to an interferometer that employs an amplified piezoelectric actuator to drive or move one or more reflectors. Use of such an actuator allows the position of the reflector to be accurately known.

For example, the position of the reflector can be determined from the voltage applied to the amplified piezoelectric actuator (referred to herein as “actuator” or “APA”). In this instance, the driving voltage applied to the actuator provides an applied electric field, and this driving voltage can be directly correlated to the extent of deformation of the piezoelectric material within the actuator. This deformation, in turn, can be characterized as a displacement of the piezoelectric material along a certain axis. In certain instances, stacks of piezoelectric elements may be employed. In other instances, a single piezoelectric element is employed. Furthermore, the piezoelectric material (including stacks thereof) can be disposed within a mechanically flexible frame, which can mechanically amplify the deformation of the piezoelectric material. Additional details regarding amplified piezoelectric actuators are described herein. Such a displacement, including mechanically amplified displacement, can be used to move one or more reflectors. In this way, the position of the reflector can be determined from the applied driving voltage.

In another example, the position of the reflector can be determined by a gauge associated with the APA. Such gauges can include displacement or positional gauges, such as a strain gauge or a capacitance gauge. One or more gauges may be physically associated or attached to the APA, such as the piezoelectric material of the actuator, a coating or film encapsulating the piezoelectric material, a frame or flexure of the actuator, and the like. In some embodiments, the gauge is any that can be configured to sense the physical movement of the APA.

As described herein, use of the APA (either alone or in conjunction with one or more gauges) allows the position of the reflector to be determined. Thus, in one non-limiting embodiment, such use eliminates the need to have a further optical system to measure the position of the moving reflector. In another embodiment, while not necessary, the interferometer may be used with an optical system to redundantly measure or independently confirm a position of the moving reflector. Such an optical system can include, e.g., a secondary laser-based optical system to measure the position of the moving reflector(s) during operation.

Generally, interferometers are critical components of modern spectrometers and many other analytical instruments. Interferometers give spectrometers a multiplexing advantage, which means that spectra can be collected much faster, have lower signal to noise ratios, and are more reproducible than spectra obtained with a dispersive spectrometer. While there are many different types of interferometers, a non-limiting example of an interferometer is the Michelson interferometer.

The Michelson interferometer uses a beamsplitter to split incoming light from a light source into two separate beams. These two light beams are then reflected off of mirrors back toward the beamsplitter, where they are recombined and then directed towards a target, such as a detector or a screen. The intensity of light arriving at a target after passing through a Michelson interferometer is affected by the wavelength of the light and the difference in optical path length followed by the two beams of light before they are recombined. By physically moving one of the two mirrors back and forth while holding the other mirror stationary or physically moving both mirrors such that one moves forward while the other moves back, it is possible to generate an interference pattern or interferogram.

In use, the interferometer can be optimized for use in any region of the electromagnetic spectrum and can be used with various applications such as, but not limited to spectroscopy. In one non-limiting embodiment, the interferometer is optimized for use in infrared light (IR, e.g., from about 700 nm to 1 mm), near-infrared light (NIR, e.g., from about 780 nm to 3000 nm, 780 nm to 2500 nm, 750 nm to 3000 nm, 750 nm to 2500 nm, 750 nm to 1400 nm, 700 nm to 3000 nm, 700 nm to 2500 nm, 700 nm to 1000 nm, and ranges therebetween), long-wavelength infrared light (LWIR, e.g., from about 8 μm to 15 μm, 8 μm to 12 μm, 7 μm to 15 μm, 7 μm to 14 μm, and ranges therebetween), mid-wavelength infrared light (MWIR, e.g., from about 3 μm to 50 μm, 3 μm to 25 μm, 3 μm to 8 μm, 3 μm to 5 μm, and ranges therebetween), or short-wavelength infrared light (SWIR, e.g., from about 1.4 μm to 3 μm, 1 μm to 3 μm, 1 μm to 2.5 μm, and ranges therebetween) regions.

In one instance, Fourier Transform infrared (FTIR) and near-infrared (FT-NIR) spectrometers can employ Michelson interferometers. These instruments generate an interferogram by measuring and digitally recording the intensity of light arriving at the detector as a function of the distance the moving mirror is displaced from a reference point, then using a Fourier Transform algorithm to transform the interferogram into a spectrum (intensity versus frequency or wavelength). The resolution of an instrument in the frequency domain (typically measured in “wavenumbers,” which are also known as reciprocal centimeters or cm⁻¹) is inversely proportional to the stroke length of the moving mirror. For example, to obtain a spectrum with a 10 cm⁻¹ resolution, the moving mirror must travel a distance of 1 mm. The precision (typically measured as the signal to noise ratio) is dependent on instrument design and generally can be improved by averaging multiple spectra collected during successive strokes of the moving mirror.

Instruments that use Michelson interferometers can be highly vulnerable to vibration, because the moving mirror must be held in near perfect alignment while it is moving. To reduce the vulnerability of a spectrometer to vibration, both the moving mirror and the stationary mirror can be replaced with corner cube retroreflectors. Corner cube retroreflectors are assemblies of three mirrors that are mutually orthogonal to each other. Any light that enters a corner cube retroreflector is reflected back towards the source regardless of minor misalignment or vibration. Thus, Michelson interferometers that use corner cube retroreflectors in place of flat mirrors are intrinsically easier to align and much less sensitive to vibration. In one embodiment, the interferometer disclosed herein can employ one or more corner cube retroreflectors as the reflector.

Various linear electromechanical, hydraulic, and pneumatic actuators can be used to drive the physical motion of the moving reflector(s). In use, these actuators can be used to move the mirror or moving corner cube retroreflector smoothly and linearly over a distance (e.g., of about 1 mm for low resolution spectrometers to about 1 cm or more for high resolution spectrometers), while optical alignment of the reflector is maintained.

Furthermore, it may be useful to know the exact position of the moving reflector at any instant in time, so that the position of the moving reflector can be related to the intensity of the light arriving at the detector. While electromechanical, hydraulic, and pneumatic linear actuators are capable of providing smooth linear motion, the extent of physical displacement may not be controlled with sufficient accuracy to determine the precise position of a moving reflector within a Michelson interferometer. Therefore, in order to accurately determine the position of the moving reflector, most commercial spectrometers use a secondary laser-based optical system to continuously measure the position of the moving reflector. Inclusion of a secondary laser-based optical system adds considerable complexity and expense to the design of spectrometers. Described herein are interferometers and systems thereof that employ one or more amplified piezoelectric actuators (APAs), which can avoid such a secondary optical system in some instances.

In some embodiments, the interferometer can include one or more optical components configured to receive and/or transmit light; and a first APA coupled to at least one of the one or more optical components. Non-limiting optical components include one or more optical sources, reflectors, mirrors, prisms, retroreflectors, retroreflector mirrors, retroreflector prisms, corner cube retroreflectors, beamsplitters, compensating plates (or compensator plates, in which these terms are used interchangeably), and the like, as well as other optical components described herein.

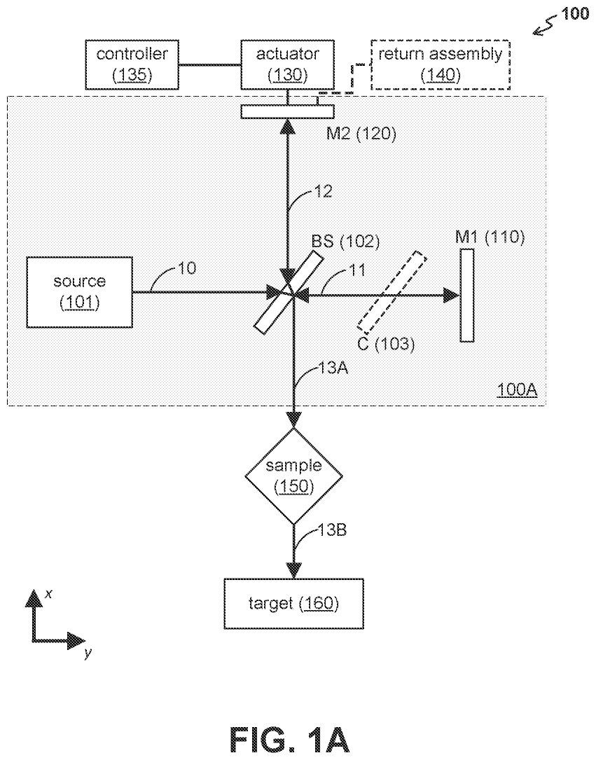

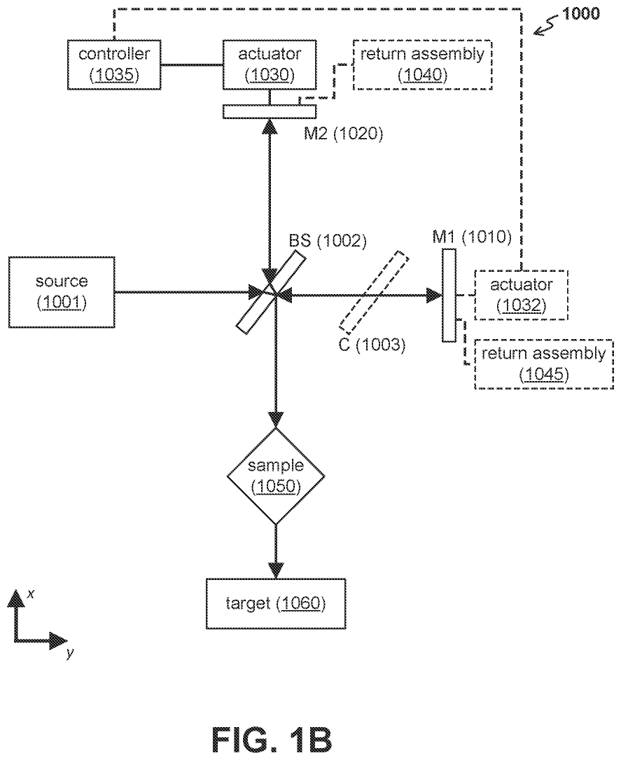

In one instance, FIG. 1A shows a non-limiting interferometer 100, which includes a non-limiting assembly 100A of one or more optical components and includes an APA 130. As can be seen, the interferometer includes various optical components, including an optical source 101, a beamsplitter BS 102, a first reflector M1 110, and a second reflector M2 120. In FIG. 1A, the optical source 101 is configured generate light (having a pathway indicated by 10), which can be directed to a beamsplitter BS 102. The beamsplitter BS 102, in turn, is configured to receive the generated light and to split the light into a first beam (having a pathway indicated by 11) to the first reflector M1 110 and into a second beam (having a pathway indicated by 12) to the second reflector M2 120. Optionally, a further optical component (e.g., a compensating plate C 103) can be placed in the pathway 11 of the first beam.

Furthermore, the beamsplitter BS 102 can be configured to receive the first and second beams transmitted from the first and second reflectors 110, 120, thereby providing a combined beam (having a pathway indicated by 13A). This combined beam can be transmitted to a sample 150, and the transmitted combined beam (having a pathway indicated by 13B) can be directed to a target 160 configured to receive this beam. The target can be any apparatus, device, or apparatus for receiving light, such as a detector, a camera, or a screen. In one instance, the target can be an object that can be used to align system components.

To change the travel distance of a split beam, one or more of the reflectors can be moved. The resolution of an interferometer is directly proportional to the travel distance of the moving reflector. Furthermore, the moving reflector can be moved at a constant velocity or can be stepped between particular points for a period of time.

As seen in FIG. 1A, a non-limiting interferometer can include the APA 130, which can be configured to drive or move an optical component (e.g., move the reflector M2 120 along the x-axis). The APA 130 can be directly or indirectly coupled to the optical component. Driving of the APA can be accomplished in any useful manner, such as by use of a controller 135 that is coupled to the APA. The controller can be configured to directly or indirectly transmit a driving signal (e.g., a driving voltage) to the APA. Additional details regarding controllers are described herein.

The APA and an optical component can be coupled (e.g., mechanically coupled), such that movement provided by the APA is directed to the coupled component. Such coupling can be direct or indirect, such as by way of one or more mounts, plates, flanges, cases, sleeves, and the like, which connect the first APA to the optical component. In one embodiment, mechanical coupling of the first APA to the optical component allows the actuator to move the optical component, such that a position of the optical component is determined by the actuator. A non-limiting example of an indirect coupling structure can include a mounting plate, which is located between the reflector and the APA. In some non-limiting instances, the coupling structure can be selected to minimize damping of the mechanical force provided by the APA.

The forward stroke action of the APA can include a movement of an optical component away from or towards another optical component. For instance, if the APA is coupled to a reflector, then the movement conferred by the APA can include moving the reflector away from or towards another optical component, such as a beamsplitter. Such a movement can be characterized by the stroke length of the APA (e.g., from about 0.3 mm to about 5 mm), the absolute distance between optical components (e.g., between the reflector attached to the APA and the beamsplitter), or the relative change in distance of the optical component.

The position of a reflector (e.g., the position of a reflector M2 120, as compared to the beamsplitter BS 102) can be determined in any useful manner. In one instance, determination of position can include determining the applied voltage to the APA. As described herein, an APA employs a piezoelectric material, which can be actuated with an applied voltage to provide a desired front stoke having a desired displacement. Typically, displacement versus applied voltage curves can be generated for an APA, and the applied voltage can be correlated to the expected displacement for the forward stroke. In this way, the extent of displacement provided by the APA can be controlled, and the change in position of the M2 (provided by such displacement) can be determined. In some embodiments, exact displacement for the forward and back strokes can be determined. For example and without limitation, the forward stroke and the back stroke can follow different voltage versus displacement paths (or curves), and models (e.g., algorithms in the software) can be employed to calculate the exact displacement for the forward and back strokes.

In another instance, a determination of the position can include sensing the physical movement or a position of the APA by using a gauge that is associated with the APA. For example, a strain gauge or a capacitance gauge may be employed.

The APA can be characterized as having a forward stroke and a back stroke. For instance, an APA typically operates in a reciprocating action, in which the forward stroke provides a first direction of movement and a back stroke provides an opposing direction of movement. In one non-limiting instance, the forward stroke can include a push force provided by the APA, which in turn pushes the moving optical component (directly or indirectly attached to the APA) towards another optical component (e.g., a stationary beamsplitter). In turn, the back stroke can include a pull force provided by the APA, which pulls the moving optical component away from another optical component (e.g., a stationary beamsplitter). In another non-limiting instance, the forward stroke can include a pull force, and the back stroke can include a push force.

Without wishing to be limited by mechanism, an APA generally has a much higher maximum push force, as compared to the maximum pull force. In some instances, it may be desirable to equalize the push and pull forces, thereby allowing the attached optical component to return to its reference point or initial position (e.g., during a particular cycle). To compensate for a lower pull force, the interferometer may optionally include a return assembly. As seen in FIG. 1A, the interferometer 100 can include a return assembly 140, which is configured to provide a supplemental pull force for the second reflector M2 120. In reference to this figure, the pull force provides a translation movement of the second reflector M2 120 away from the beamsplitter BS 102.

The return assembly can be configured in any useful manner to provide a supplemental force. In one instance, if a coupling structure is present between a reflector and the APA, then the return assembly can be directly or indirectly coupled to that coupling structure, thereby allowing the supplemental force provided by the return assembly to be directed to the reflector.

Furthermore, the supplemental force can be provided in any useful way. In one non-limiting instance, the supplemental force is provided by way of one or more springs, which provides an additional pull force to the reflector on a back stroke. In use, the spring(s) can be compressed or stretched in a forward stroke by the APA, thereby allowing the spring(s) to provide the supplemental pull force that translates the reflector on a back stroke. Other compressible structures can be employed to provide a supplemental force. Non-limiting compressible structures can include an inflated structure (e.g., an air bag), an elastomeric or rubber material, and the like.

An interferometer can include any useful number of optical components, actuators, and return assemblies, which can be positioned and arranged in any useful manner. In one instance, a first APA can be associated with a first reflector, and a second APA can be associated with a second reflector. In another instance, a first return assembly can be associated with a first reflector, and a second return assembly can be associated with a second reflector. In yet another instance, a single APA can be associated with a first reflector and a second reflector, and one or more return assembly can be associated with the first and second reflectors. In this way, any manner of arranged actuator(s) and return assembly(ies) can operate to move one or more optical components, such as one or more reflectors.

FIG. 1B shows another non-limiting interferometer 1000, which includes various optical components, including an optical source 1001, a beamsplitter BS 1002, a first reflector M1 1010, an optional compensating plate C 1003, and a second reflector M2 1020. A split and combined beam from the beamsplitter BS 1002 can be transmitted to a sample 1050 and then to a target 1060 configured to receive this transmitted beam. As can be seen, an actuator 1030 is coupled to the second reflector M2 1020 (e.g., to move M2 back and forth along the x-axis, as well as towards or away from the beamsplitter BS 1002), and a controller 1035 is coupled to the actuator 1030. In this way, driving of the actuator can be accomplished by use of a controller to transmit driving signals to the actuator.

As also seen in FIG. 1B, optional actuators and return assemblies may also be present. For example, an optional return assembly 1040 can be indirectly or directly coupled to the second reflector M2 1020 (e.g., to move M2 back and forth along the x-axis, as well as towards or away from the beamsplitter BS 1002), in which this return assembly 1040 can be configured to provide a supplemental force (e.g., a supplemental pull force) for the second reflector M2 1020 that equalizes the push and pull forces provided by the actuator 1030. For instance, if the actuator 1030 provides a pull force (F₁) that is lower than its push force (F₂), then the return assembly 1040 can provide a supplemental pull force (Fₛᵤₚₚ) that equalizes the push and pull forces exerted onto the second reflector M2 1020 (e.g., such that F₁+Fₛᵤₚₚ≈F₂). Thus, a return assembly may be present to compensate for differences in push and pull forces provided by the actuator.

In another example, a further actuator may be optionally present. For instance, an optional actuator 1032 may be directly or indirectly coupled to the first reflector M1 1010 (e.g., to move back and forth along the y-axis, as well as towards or away from the beamsplitter BS 1002). If this actuator is present, then the interferometer would possess at least two actuators, which can independently modify the position of the reflector to which the actuator is attached. An optional return assembly 1045 may be indirectly or directly coupled to the first reflector M1 1010 (e.g., to move along the y-axis, as well as away from the beamsplitter BS 1002), in which this return assembly 1045 can be configured to provide a supplemental force (e.g., a supplemental pull force) for the first reflector M1 1010 that equalizes the push and pull forces provided by the actuator 1032.

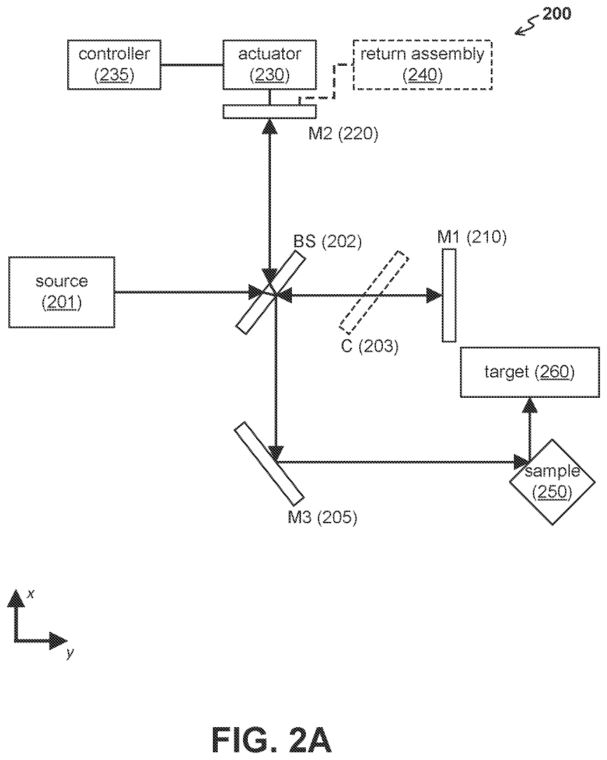

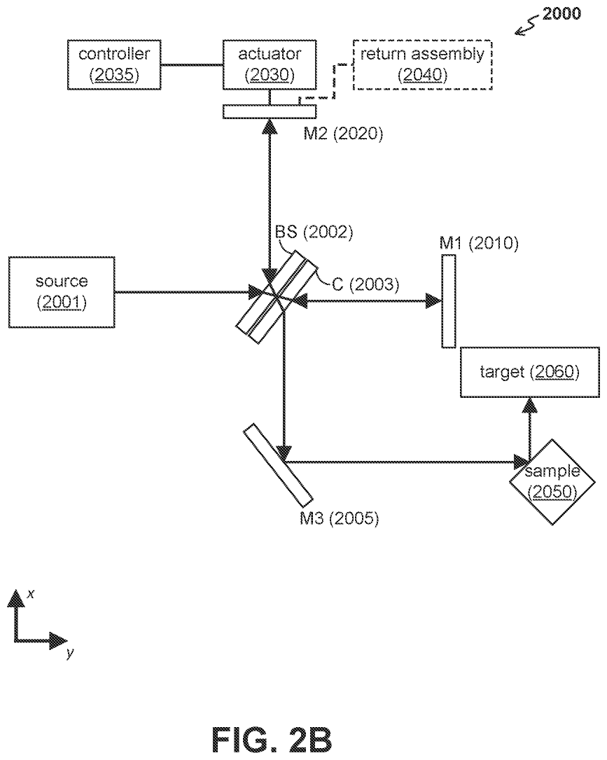

Optical components may be used to provide any useful pathway for light beams. For instance, a further reflector may be used to direct a combined beam at certain angles to provide beneficial interaction with a sample. FIG. 2A shows another non-limiting interferometer 200, which includes an optical source 201, a beamsplitter BS 202, a first reflector M1 210, an optional compensating plate C 203, a second reflector M2 220, an actuator 230 and an optional return assembly 240 coupled to the second reflector M2 220, and a controller 235 coupled to the actuator 230. As can be seen, a split and combined beam from the beamsplitter BS 202 is directed to the sample 250 by use of a third reflector M3 205. In this way, the split and combined beam can be transmitted to a sample 250 and then to a target 260 configured to receive this transmitted beam. Other configurations of optical components can be employed to properly direct light beams from the source to the sample, as well as from the sample to a further target configured to receive a transmitted beam.

In another example, FIG. 2B shows an interferometer 2000, in which the beamsplitter and matching compensating plates are directly coupled (e.g., separated by only a few micrometers, such as between about 1 to 5 μm). In some non-limiting instances, this coupled configuration can provide ease of alignment. As can be seen, the non-limiting interferometer 2000 includes an optical source 2001, a beamsplitter BS 2002 coupled to a matching compensation plate C 2003, a first reflector M1 2010, a second reflector M2 2020, an actuator 2030 and an optional return assembly 2040 coupled to the second reflector M2 2020, and a controller 2035 coupled to the actuator 2030. As can be seen, a split and combined beam (from the coupled BS 2002 and C 2003) is directed to the sample 2050 by use of a third reflector M3 2005. In this way, the split and combined beam can be transmitted to a sample 2050 and then to a target 2060 configured to receive this transmitted beam. In some embodiments, the position of the source 2001 and the target 2060 (e.g., a detector) can be switched.

As discussed herein, the resolution of an interferometer is directly proportional to the travel distance of the moving reflector. APAs are generally capable of movement up to about 1 mm. Thus, when an APA is used to linearly translate a single reflector, then the difference in optical path lengths (between first and second reflectors and determined after actuation) can be up to about 1 mm. Mechanical amplification may be used for travel distances greater than about 1 mm. Mechanical amplification can include the use of an arm assembly having a pivot point, in which an initial displacement provided by the APA is mechanically amplified by simultaneously decreasing a path length of a first light beam and increasing a path length of a second light beam during the first half of the cycle. During the second half of the cycle, the directions of movement are reversed. In this way, the difference between optical path lengths can be greater than about 1 mm. With greater length of movement, the spectrometer will have higher theoretical resolution, which may be constrained by other optical or mechanical considerations. In one embodiment, the difference in optical path length between the first and second reflectors is from about 0.3 mm to about 5 mm.

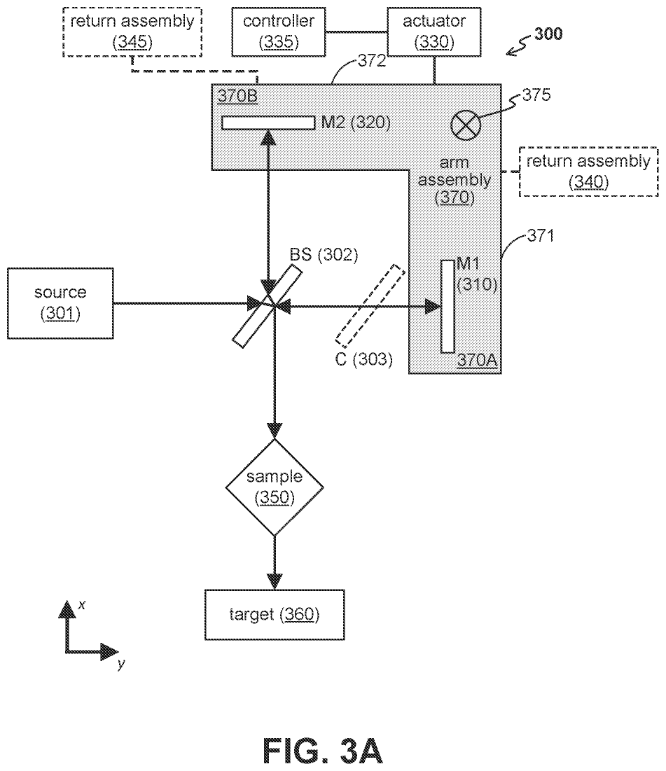

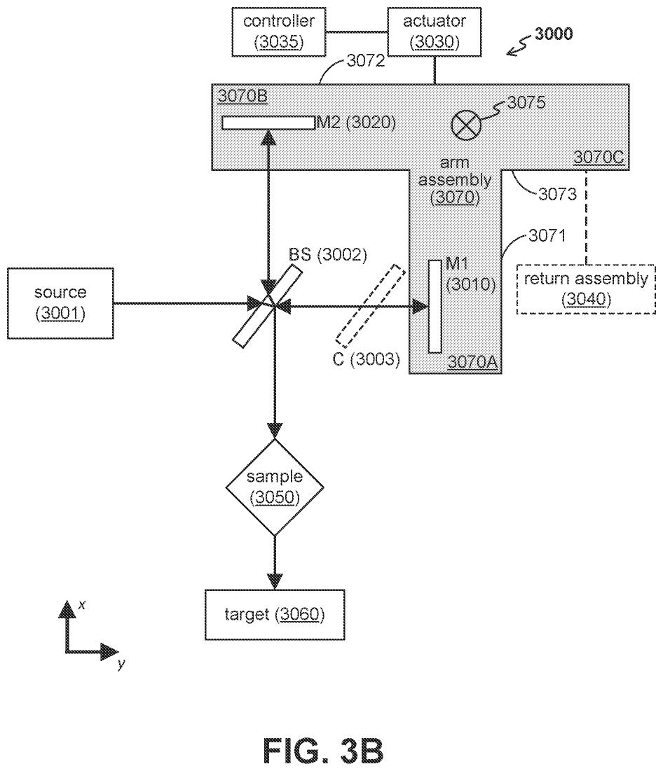

FIG. 3A provides a non-limiting interferometer 300 that includes an arm assembly 370. As can be seen, the non-limiting interferometer 300 includes various optical components, such as an optical source 301, a beamsplitter BS 302, a first reflector M1 310, a compensating plate C 303, and a second reflector M2 320. A compensating plate can be coupled with the beamsplitter or separated from the beamsplitter. If the beamsplitter is a plate beamsplitter, then a compensating plate can be used. If the beamsplitter is a cubic beamsplitter, then a compensating plate is not used. A split and combined beam from the beamsplitter BS 302 can be transmitted to a sample 350 and then to a target 360 (e.g., a detector or a screen) configured to receive this transmitted beam.

As can be seen, the arm assembly 370 interacts with the first reflector M1 310 and the second reflector M2 320, as well as the actuator 330. In particular, the arm assembly 370 includes a surface disposed over a first arm 370A and a second arm 370B, and the first and second reflectors 310, 320 are disposed on this surface. In this way, the relational position between the first and second reflectors are fixed because these reflectors are fixed to the surface of the arm assembly. In one embodiment, to ensure optimal alignment of the reflectors to the beamsplitter during movement of the arm assembly, the reflectors can be corner cube retroreflectors that move in tandem when the arm assembly is pushed or pulled by the actuator.

As can also be seen, the arm assembly 370 includes a pivot point 375 around which the first and second arms 370A, 370B can rotate. The arm assembly 370 further includes a first outer edge 371 and a second outer edge 372, in which the second outer edge 372 is directly or indirectly coupled to the actuator 330. However, either edge may be coupled to the actuator.

In use, the actuator 330 can be used to move the second arm 370B away from and towards the beamsplitter BS 302 (or pushed and pulled from the beamsplitter), thereby changing the optical path length between the beamsplitter BS 302 and the second reflector M2 320. With any movement that moves the second arm 370B away from the beamsplitter BS 302, the first arm 370A would move towards the beamsplitter BS 302. Conversely, with any movement that moves the second arm 370B towards the beamsplitter BS 302, the first arm 370A would move away from the beamsplitter BS 302. In this way, the direct displacement provided by the actuator 330 by contacting the second arm 370B would be greater than the difference in optical path length between the first and second reflectors 310, 320 (as determined for an optical path length between the beamsplitter BS 302 and a first reflector 310 and another optical path length between the beamsplitter MS 302 and a second reflector 320).

One or more return assemblies may be coupled to the arm assembly. As seen in FIG. 3A, an optional first return assembly 340 may be coupled to a first arm 370A, and/or an optional second return assembly 345 may be coupled to a second arm 370B. A controller 335 may be coupled to the actuator 330, as well as optionally coupled to the return assemblies 340, 345.

While two arms are shown in FIG. 3A, the arm assembly may include a single arm that is continuously curved and attached to a pivot point at any position along the single arm. Alternatively, the arm assembly can include more than two arms. In one non-limiting instance, FIG. 3B provides a non-limiting interferometer 3000 that includes an arm assembly 3070. As can be seen, the non-limiting interferometer 3000 includes various optical components, such as an optical source 3001, a beamsplitter BS 3002, a first reflector M1 3010, a compensating plate C 3003, and a second reflector M2 3020. A compensating plate can be coupled with the beamsplitter or separated from the beamsplitter. If the beamsplitter is a plate beamsplitter, then a compensating plate can be used. If the beamsplitter is a cubic beamsplitter, then a compensating plate is not used. A split and combined beam from the beamsplitter BS 3002 can be transmitted to a sample 3050 and then to a target 3060 (e.g., a detector or a screen) configured to receive this transmitted beam.

As can be seen, the arm assembly 3070 interacts with the first reflector M1 3010 and the second reflector M2 3020, as well as the actuator 3030. In particular, the arm assembly 3070 includes a surface disposed over a first arm 3070A, a second arm 3070B, and a third arm 3070C; and the first and second reflectors 3010, 3020 are disposed on the surface disposed over the first and second arms 3070A-B.

As can also be seen, the arm assembly 3070 includes a pivot point 3075 around which the first, second, and third arms 3070A-C can rotate. The arm assembly 3070 further includes a first outer edge 3071, a second outer edge 3072, and a third outer edge 3073, in which the second outer edge 3072 is directly or indirectly coupled to the actuator 3030. However, any of these edges may be coupled to the actuator.

In use, the actuator 3030 can be used to move the second arm 3070B away from and towards the beamsplitter BS 3002 (or pushed and pulled from the beamsplitter), thereby changing the optical path length between the beamsplitter BS 3002 and the second reflector M2 3020 and between the beamsplitter BS 3002 and the first reflector M1 3010.

One or more return assemblies may be coupled to the arm assembly in any useful manner. As seen in FIG. 3B, an optional return assembly 3040 may be coupled to a third arm 3070C, but the optional return assembly 3040 or further return assemblies may be coupled to the first and/or second arms 3070A-B. A controller 3035 may be coupled to the actuator 3030, as well as optionally coupled to the return assembly 3040.

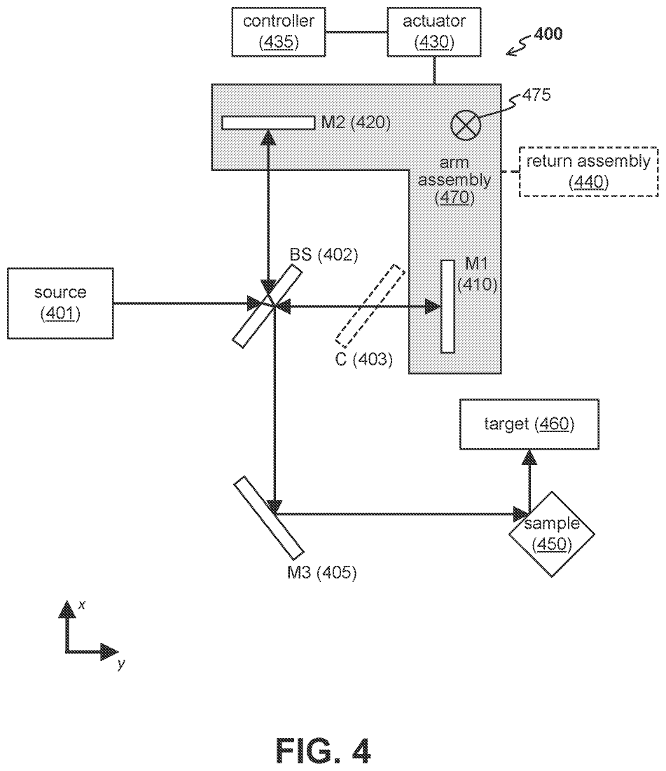

In addition to having an arm assembly with two reflectors, the interferometer can include further reflectors. As seen in FIG. 4, another non-limiting interferometer 400 includes various optical components, such as an optical source 401, a beamsplitter BS 402, a first reflector M1 410, a compensating plate C 403, a second reflector M2 420, an actuator 430 and an optional return assembly 240 coupled to an arm assembly 470 having a pivot point 475, and a controller 435 coupled to the actuator 430. A compensating plate can be coupled with the beamsplitter or separated from the beamsplitter. If the beamsplitter is a plate beamsplitter, then a compensating plate can be used. If the beamsplitter is a cubic beamsplitter, then a compensating plate is not used. As can be seen, a split and combined beam from the beamsplitter BS 402 is directed to the sample 450 by use of a third reflector M3 405. In this way, the split and combined beam can be transmitted to a sample 450 and then to a target 460 configured to receive this transmitted beam. Other components, devices, and structural elements may be provided within interferometers and systems thereof, as described further herein.

Amplified Piezoelectric Actuators

Piezoelectric crystals and ceramics generate an electrical charge when compressed. Conversely, piezoelectric materials can be used as actuators because they change shape when electrically charged. For example, the physical dimensions of a piezoelectric ceramic will typically change by a few microns over an applied voltage range (e.g., typically 0 to about 200 V). By precisely controlling the applied voltage, the travel distance or stroke length of a piezoelectric actuator can be controlled (e.g., to the sub-nanometer level). Most piezoelectric actuators have a stroke length of only a few microns, which is too short of a distance to drive a moving mirror or moving corner cube retroreflector in a Michelson interferometer. However, it is possible to stack multiple piezoelectric elements to make a linear actuator that can precisely control movement over a few tens of microns.

Furthermore, a piezoelectric actuator (e.g., having a stack of piezoelectric elements) can be attached to a flexible apparatus to make a mechanically amplified piezoelectric actuator with travel distances of 100 micrometers to 1 mm or more. These amplified piezoelectric actuators can be precisely controlled (e.g., within a nanometer range) by controlling the applied voltage to the piezoelectric stack. The flexible apparatus can include one or more mechanically flexible constructs to mechanically amplify a movement conferred by the piezoelectric material. The flexible apparatus can include deformable flexures, frames, and the like.

Non-limiting piezoelectric materials include lead zirconate titanate (Pb[ZrxTiix]O₃ with 0≤x≤1 (PZT), potassium niobate (KNbO₃), sodium tungstate (Na₂WO₃), sodium potassium niobate ((K,Na)NbO₃), and the like. Furthermore, such materials can be in any useful form (e.g., elements, chips and the like), which can be provided in stacks having a plurality of piezoelectric elements (e.g., elements including a piezoelectric material).

The APA can be configured to provide any useful movement of the reflector(s). Such movement can include translational linear movement, translational rotational movement, displacement in any direction from a reference point or an initial position, and the like. Such movement can include those in one or more directions (e.g., forward and/or backward direction) and for any useful distance (e.g., from about 0.3 mm to 5 mm). In one embodiment, the APA is configured to translate (or move) the moving optical component both away and towards another optical component (e.g., a stationary beamsplitter).

Within an interferometer or a system including such an interferometer, one or more APAs may be present. For instance, a first APA can be associated with a moving optical component, and a second APA can be associated with another moving optical component. The first and second APAs can be configured to be operated in tandem. For instance, a first reflector can be configured to move in a same direction as a second reflector, relative to a stationary optical component (e.g., a beamsplitter). In other embodiments, the first reflector can be configured to move in a different direction as the second reflector, relative to a stationary optical component (e.g., a beamsplitter). During operation, one reflector will typically be moving towards the beamsplitter, while the other reflector is moving away from the beamsplitter. The directions will then reverse with each half cycle.

Furthermore, the APA(s) can be operated in any useful manner. In one non-limiting instance, an interferometer can include use of an APA in an open-loop configuration, in which the voltage driving the actuator is used to determine the position of the moving reflector(s). In another non-limiting instance, the interferometer can include use of an APA in a closed-loop configuration, in which either the voltage controlling the actuator or a sensing gauge (e.g. a strain gauge or a capacitance gauge) is used to determine the position of the moving reflector(s) coupled to the APA.

In use, the APA can be associated with any useful component, such as one or more controllers, circuits, and the like. In one instance, the APA can further include a low noise circuit configured to provide one or more output voltages to drive the APA. Such output voltage(s) can be configured to provide a position of the moving reflector(s) coupled to the APA. In another instance, the APA can further include a circuit configured to employ a signal from the sensing gauge as an input signal for the circuit. Such circuits can include one or more amplifiers, feedback loops, control loops, and the like.

To transmit and receive signals from the APA, the interferometer can include a controller coupled to the APA. In particular embodiments, the controller can be configured to directly or indirectly transmit a driving signal (e.g., a driving voltage) to the APA and to optionally receive a signal from a sensing gauge associated with the APA. In other embodiments, the controller can be further configured to power and control the one or more APAs.

Any useful sensing gauge may be associated with the APA (e.g., associated in proximity to the APA, associated with the piezoelectric material of the APA, associated with the flexible apparatus of the APA, and/or associated with a film or coating of the APA). Non-limiting gauges include Wheatstone bridge circuits, strain gauges, capacitance gauges, and the like.

Further descriptions of piezoelectric actuators and components thereof (e.g., piezoelectric materials, stacks, and the like), amplified piezo actuators, actuator systems, actuator devices, piezoactive actuators, mechanical movement amplifiers, mechanical coupling elements, piezo linear drives, circuit arrangements for piezoelectric actuators, and the like are described in U.S. Pat. Nos. 5,270,790, 6,147,436, 6,617,754, 6,927,528, 9,117,997, 9,748,468, 9,960,340, and 10,580,959, and in U.S. Pat. Pub. Nos. 2003/0085633, 2007/0043451, 2022/0066557, each of which is incorporated herein by reference in its entirety.

Return Assembly

One or more return assemblies can be associated with the moving reflector(s). Such associations may include direct coupling with the moving reflector(s), as well as indirect coupling (e.g., by way of mounts, flanges, and the like; as well as by way of an arm assembly, as described herein). Typically, the APA provides both a push and a pull force, in which these forces are not equal. A return assembly may be used to provide a supplemental force (e.g., generally a supplemental pull force) to compensate for any differences in the push and pull forces provided by the APA.

Without wishing to be limited by mechanism, APAs generally have a much higher maximum push force than maximum pull force. Indeed, if the resistance force exceeds either of these maximums, the actuator can catastrophically fail. The purpose of a return assembly spring can be, in part, to add a supplemental pull force. For example, and without limitation, if an APA has a maximum push force of about 100 N and a maximum pull force of about 5 N, then a return assembly can be designed to provide an additional 47.5 N to the pull force. This equalizes the maximum push and pull forces, both at 52.5 N, and hence reduces the chance of a catastrophic failure. As can be seen, the optimum force of the return assembly will vary depending on the maximum push and pull forces of the APA that is being used. In one instance, the return assembly provides a supplemental force from about 20 N to 80 N.

In one non-limiting instance, the return assembly includes one or more springs. Such springs can be integrated with a coupling structure that is, in turn, coupled to the moving reflector. The spring can be either compressed or stretched when the APA moves the moving reflector in one direction (e.g., as in a forward stroke) and then provides a supplemental force that helps move the moving reflector in the reverse or opposite direction (e.g., as in a back stroke). In this way, the forward stroke of the APA loads the spring to provide the supplemental force in the back stroke. Non-limiting springs can include compression springs, wave springs, cantilever springs, coil springs, disc springs, tension springs, and the like.

The return assembly can include any device that stores and releases mechanical energy. In particular non-limiting embodiments, the device is configured to provide a counteracting, supplemental force to a force provided by an APA in a forward stroke. In other embodiments, a magnitude of the supplemental force provided by the device is configured to equalize a maximum push force and/or a maximum pull force of the APA. In yet other embodiments, the device is configured to translate (or move) the moving optical component away from another optical component (e.g., a stationary beamsplitter). Non-limiting examples of devices include one or more springs, elastic structures, inflated structures, compressed structures, and the like.

Guide Assembly

The path of a moving component can be directed by use of one or more optional guide assemblies. For instance, a moving reflector can be associated with a guide assembly that provide a path for travel upon being pushed or pulled by an APA. For ease of integration, the moving reflector can include a mount that associates with the guide assembly. Such a mount can include mounting holes, pins, recesses, and the like, which can then be used for attachment to a guide assembly.

In some embodiments, the guide assembly can include a stationary base that provides the path for travel, as well as a mobile component that moves along the path. The stationary base can include any useful structure, including rods, shafts, grooves, tracks, rails, and the like to define the direction of the path. The mobile component can include plates, holders, carriers, flanges, and the like that integrates with the stationary base and moves along the path defined by the stationary base. Components can be present to reduce friction during movement, such as bearings, coatings, and the like. Non-limiting systems for guide assemblies include sleeve bearing, guide bearing, magnetic bearing, or similar bearings to control the alignment of the moving reflector(s) while moving. Such systems can be configured to align the moving reflector(s) (e.g., the first reflector and/or the second reflector) when moving away from or towards another optical component (e.g., a stationary optical component, such as a stationary beamsplitter). Such an alignment can be along an intended axis of motion (or a path) that is towards and away from the beamsplitter.

Arm Assembly

During operation of an interferometer having an arm assembly, one reflector can be moving towards the beamsplitter, while another reflector is moving away from the beamsplitter. The directions will reverse with each half cycle. An arm assembly may be used to mechanically amplify the distance traveled by the moving reflector(s) during each cycle. This increases the difference between the optical path lengths of the first and second light beams within the interferometer, which increases the resolution of the spectrometer.

The arm assembly associates with the moving optical components, as well as the APA(s). In this way, actuation of the APA moves the arm assembly, which in turn moves the moving optical components. The mechanical linkage between arm assembly and actuator can employ any useful device. Non-limiting linkage devices include a pivot bearing, which can optionally include bearing support, rotational bearings, cams, bushings, flexures, and the like.

Depending on the type of movement provided by the arm assembly, particular types of moving reflectors may be useful. For instance, as described in FIG. 3A, the arm assembly 370 includes a pivot point 375 upon which the assembly rotates. Due to such rotational movement, it may be difficult to maintain alignment if the moving reflectors are flat mirrors. Thus, in some instances, the moving reflector may be selected to be corner cube retroreflectors.

In one embodiment, the arm assembly includes a surface and a pivot point, in which one or more moving reflectors are disposed on the surface of the arm assembly. The arm assembly may include one or more outer edges, in which one outer edge is directly or indirectly coupled to an APA. Furthermore, the APA can be configured to move the arm assembly about the pivot point, thereby moving the one or more reflectors, independently, away from or towards the beamsplitter.

The arm assembly may include a continuous arc as an arm, in which the pivot point is located at any position of this arc. Alternatively, the arm assembly may include a plurality of arms, and the pivot point can be located at any position of this assembly. In one embodiment, the pivot point is located at a centroid position of the assembly. In another embodiment, the arm assembly includes a first portion (or a first arm) and a second portion (or a second arm), in which the first and second portions extend away from the pivot point. The moving reflector(s) may be positioned at any location of the arm(s) or arm assembly. In one instance, a first reflector is disposed on a surface of the first portion (or a first arm), and a second reflector is disposed on a surface of the second portion (or a second arm).

The arm assembly may be associated with one or more return assemblies to compensate for differences in push and pull forces provided by the APA. For example, a return assembly can be configured to be directly or indirectly coupled to the arm assembly (or an edge of the arm assembly), in which the return assembly is configured to provide a force that moves the arm assembly in an opposite direction than a movement provided by an APA. The return assembly may be coupled to any portion of the arm assembly, such as by use of any coupling or linkage strategies described herein.

The return assembly may be coupled any edge of an arm of the arm assembly, e.g., as seen in FIG. 3A-3B herein. In one instance, the APA is indirectly or directly coupled to a first edge of the arm assembly, and the return assembly is also coupled to that first edge. In another instance, the return assembly is directly or indirectly coupled to a second edge of the return assembly, in which this second edge is orthogonal to (or perpendicular to) the first edge. In yet another instance, the return assembly is directly or indirectly coupled to a third edge of the return assembly, in which the third edge is different than the first edge.

Optical Components

The interferometers herein can include an arrangement of various optical components. Non-limiting optical components include one or more optical sources (or light sources), reflectors, beamsplitters, compensating plates, and the like. For any embodiment or configuration described herein, the positions of optical components can be switched or otherwise modified. For instance, the positions of the optical source and the detector can be switched. For any embodiment or configuration described herein, additional optical components can be included, or one or more optical components can be substituted for one or more other optical components. In one instance, various lenses and/or mirrors can be included to focus the light. In another instance, optical fibers, fiber optic cables, or hollow light pipes can be used to direct light from one position to another (e.g., from the sample to the interferometer or to the detector). In another instance, an assembly to insert and retract a reference standard into the optical path may be included.

In yet another instance, one type of detector can be substituted with another type of detector, or one type of substrate can substituted with another type of substrate. Numerous other modifications and substitutions can occur to those skilled in the art without departing from the scope of this disclosure.

The optical source can be selected to have any useful properties, such as wavelength, coherence, power, collimation, and the like. In one instance, the optical source can have a wavelength in the IR, NIR, LWIR, MWIR, or SWIR region. The optical source can include a collimated beam, such as provided by a laser, an optical cavity, and the like. Alternatively, a collimated beam may be obtained by using a parabolic reflector, a spherical mirror, a collimating lens, and the like. An optical source can include any useful thermal emission source, such as a globar or filament, a diode, or a laser such as a quantum dot laser, a quantum cascade laser, an optical cavity, a laser diode, a light emitting diode, a frequency comb laser, etc.

Reflectors can be used to receive and transmit light beams. Examples of reflectors (e.g., such as for use as a first reflector and/or a second reflector) include a mirror (e.g., one or more flat mirrors, parabolic mirrors, elliptical mirrors, off-axis parabolic mirrors, or combinations thereof), a prism, a retroreflector, a retroreflector mirror, a retroreflector prism, or a corner cube retroreflector. Such reflectors can be configured to be moving or stationary. One or more reflectors may be configured to move within an interferometer.

Beamsplitters can be used to split and combine light beams. Non-limiting examples of beamsplitters include a plate beamsplitter, a cubic beamsplitter, and the like. Depending on the choice of the beamsplitter, certain other optical components may be avoided or included. In one instance, if the beamsplitter is a plate beamsplitter, then a compensating plate is included. In another instance, if the beamsplitter is a cubic beamsplitter, then a compensating plate is avoided.

The apparatuses and systems herein can include other optical components to direct, receive, transmit, reflect, filter, or otherwise modify a light beam. Such optical components include can one or more compensating plates, polarizers, filters, focusing mirrors, flat mirrors, internal reference standards, parabolic mirrors, elliptical mirrors, off-axis parabolic mirrors, beam expanders, masks, lenses, windows, optical fibers, fiber optic cables, hollow light pipes, and the like. Any optical component herein can be used together to provide a desired optical path. For instance, a compensating plate may be matched to a plate beamsplitter in order to make the optical paths of the two beams of light equal. In other instances, the interferometer can include a cubic beamsplitter in place of a plate beamsplitter, which can obviate the use of an associated matching compensating plate in the optical path.

An internal reference standard can be used, in which a reference material (e.g., any known, useful material) is inserted into an optical path for purposes of checking alignment and/or for calibrating spectra. For example, the reference material can be a material having known absorbance(s) at known specific wavelengths, and such a material can be used as an internal reference standard for the purpose of calibration and/or checking the optical alignment of the interferometer. The reference standard can be formed from any useful material, such as a polystyrene film (e.g., a thin polystyrene film), and the like.

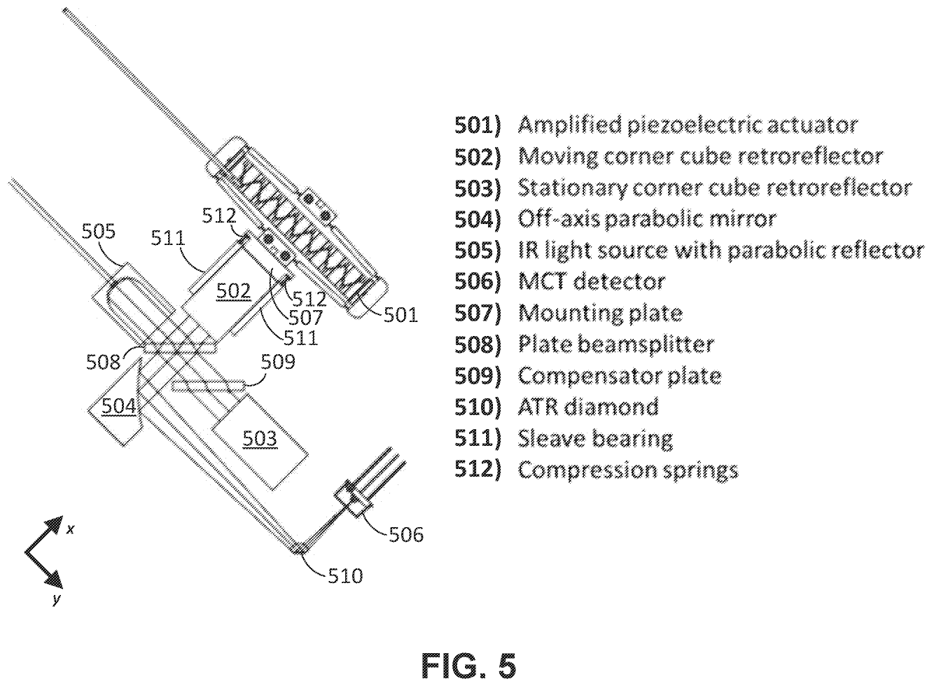

The reference standard can be inserted at any useful position within the optical path. In some embodiments, the position is disposed between a reflector and a substrate for the sample (e.g., in FIG. 5, the position can be disposed between the off-axis parabolic mirror 504 and the ATR diamond substrate 510; in FIG. 1A, the position can be disposed in an optical pathway 13A between the beamsplitter BS 102 and the sample 150; and in FIG. 2A, the position can be disposed between the third reflector M3 205 and the sample 250 or between the beamsplitter BS 202 and the third reflector M3 205). Other positions within other optical paths are possible.

An assembly can be used to insert and retract (e.g., on command of the controller) the reference material into and out of an optical path. Non-limiting examples of assemblies can include a stationary base (e.g., any described herein) that provides a path for travel, as well as a mobile component (e.g., any described herein) that moves along the path. In some embodiments, the reference material can be disposed on or otherwise coupled to the stationary base. The mobile component can be optionally coupled to a motor or actuator, and a controller can be used to transmit signals to the motor or actuator to move the reference standard into or out of an optical path. Alternatively, one or more optical components such as mirrors could be inserted to redirect the optical path, such that the light passes through a reference material that has absorbance(s) at known specific wavelengths for the purpose calibration and/or checking optical alignment.

Targets

The apparatuses and systems herein can include one or more targets to receive a combined beam. Such targets can include a detector, which can be configured to receive a combined beam directed from a beamsplitter. In other embodiments, the target can be a screen or an object (for example to align system components).

In one embodiment, the target is a detector capable of measuring the intensity of the light arriving at the detector. In particular instances, the detector is configured to measure IR, NIR, LWIR, MWIR, or SWIR light. Non-limiting examples of detectors include a photodiode, a photoresistor, a quantum well photodetector (e.g., a quantum well infrared photodetector (QWIP)), a quantum dot detector (QDD), a quantum cascade detector (QCD), a photoacoustic detector, a thermal detector, a thermocouple, a thermopile detector, a pyroelectric detector, a type II superlattice detector, a bolometer, a microbolometer, a passive sensor (e.g., a passive infrared (PIR) sensor), and the like, in which each of these detectors may be uncooled, cooled, or thermally controlled.

Such detectors can be formed from any useful material, such as mercury cadmium telluride (MCT or HgCdTe, such as in, e.g., MCT detectors), mercury zinc telluride, lead salts (e.g., lead(II) sulfide (PbS), lead selenide (PbSe), and the like), III-V materials (e.g., indium gallium arsenide (InGaAs), indium arsenide (InAs), gallium arsenide (GaAs), aluminum gallium arsenide (AlGaAs), indium antimonide (InSb), indium arsenide antimonide (InAsSb), and the like; such as in InGaAs photodiode detectors), perovskites (e.g., lithium tantalate (LiTaO₃)), ferroelectric materials, pyroelectric materials (e.g., triglycine sulfate (TGS) including doped forms of TGS, such as deuterated TGS (DTGS) or deuterated L-alanine doped TGS (DLATGS); lithium tantalate (LiTaO₃); lead zirconate titanate (PZT), and the like), semiconductor materials (e.g., platinum silicide (PtSi)), and the like, as well as combinations thereof. In one instance, the material and its constituents are chosen to tune optical absorption or bandgap to a desired infrared wavelength or range of IR wavelengths. The detector can have any useful form, such as monolithic sensors, focal plane arrays, superconducting tunnel junction arrays, and the like.

Samples and Sample Holders

Any useful sample can be characterized by the apparatuses and systems herein. In one embodiment, the sample can include any useful detectable compound, such as minerals, water, organic matter, nutrients, micronutrients, elements, and the like. The sample can include any material for analysis, such as soil samples, polymer samples, and the like. The sample can include a substrate, such as an attenuated total internal reflectance (ATR) substrate (e.g., including a crystal, diamond, zinc selenide (ZnSe), germanium, or thallium bromoiodide (KRS-5)). In particular embodiments, the sample is not preprocessed and applied to a substrate. In other embodiments, the sample is processed, such as by drying, grinding, mixing, pelleting, pressing, and the like; and then the processed sample is disposed, applied, or adsorbed onto a substrate (e.g., a window).

Furthermore, the apparatuses and systems herein can include a sample holder configured to provide a sample. In some embodiments, the sample holder is configured to interact a combined beam (e.g., transmitted from a beamsplitter) with the sample, thereby providing an interacted beam. In further embodiments, the target (e.g., a detector) can be configured to receive the interacted beam. The sample holder can include a substrate (e.g., upon which a sample is disposed) and/or an optically clear sample container.

Other Components and Systems Thereof

An interferometer can be present as an apparatus or as a part of a system (e.g., a spectrometer) that can be used for measuring spectra of light (e.g., for use in spectroscopy). An apparatus or system can further include other components or subsystems. Such components of subsystems can include, e.g., one or more controller systems, positioning systems, convertors, processors, memory devices, and displays.

A controller system can be configured to power and/or control the one or more optical sources, APAs, return assemblies, detectors, and/or other components. The controller system can also be connected to other components associated with the APA or return assembly, such as sensing gauges, amplifiers, filters, signal generators, internal reference standards, and the like.

A positioning system can be configured to determine a position of the moving optical component(s). In one embodiment, the position is determined based on the voltage driving the APA. In another embodiment, the position is determined based on a signal from an associated strain gauge, capacitance gauge, or other gauge used for sensing the movement and/or position of the actuator.

A converter can include a signal converter, a power converter, or the like. In one instance, the converter is an analog to digital converter (ADC) or similar system that is configured to digitize a signal coming from a detector. In another instance, the converter can be a digital to analog converter (DAC) that directs and controls voltage from a power supply to the APA to drive controlled motion of the APA.

A processor can include any device or apparatus configured to process data. Optionally, the processor can be associated with a memory device to store data, and the processor can be configured to receive or transmit data from the memory device. In one embodiment, the processor includes a computer, software, and/or other data recording and processing device for recording position data from the actuator and the signal coming from the detector. In another embodiment, the processor can be configured to generate an interferogram. In yet another embodiment, the processor can include software that can be executed for system control, data acquisition, and analysis, including Fourier Transform of the interferogram to generate spectra.

The processor can be configured to receive one or more signals from any useful component (e.g., APAs, return assemblies, arm assemblies, sensing gauges, and/or detectors). In some embodiments, the processor is configured to record position data from the APA, to record a signal from the detector to generate an interferogram, to correct an interferogram for non-linearity and/or hysteresis between forward and back strokes of the first amplified piezoelectric actuator, to generate an average interferogram, and/or to execute software for system control, data acquisition, data correction, data manipulation, and/or analysis including Fourier Transform of the interferogram to generate spectra.

The processor can be configured to compensate for non-linearity between voltage applied to APAs and mechanical displacement of optical components by the APAs. In some embodiments, such compensation can be different for the forward and back strokes because the applied voltage-displacement path can be different for the forward and back strokes of the APA. In some embodiments, compensation of such differences and calculation of exact displacement of the forward and back strokes can include the use of software (e.g., to implement algorithms) to calculate displacement from the voltage applied to the APA on the forward strokes and back strokes.

The processor can be configured to generate an average interferogram, which in turn can be employed prior to analysis (e.g., Fourier Transform analysis). The average interferogram can be generated in any useful manner, such as by inversion, addition, subtraction, or normalization of spectra. For example and without limitation, each complete cycle of the APA can result in the generation of four interferograms (two on the forward stroke and two on the back stroke). The two interferograms generated on the forward stroke are mirror images of each other (same for the two interferograms generated on the back stroke), hence the software must invert two interferograms for each complete cycle of the APA so that all four interferograms generated during a complete cycle of the APA can be combined to generate an average interferogram. An average interferogram from one or more complete cycle(s) of the APA can be calculated before the Fourier Transform algorithm is used to calculate a spectrum. In some embodiments, the processor is configured to combine a plurality of interferograms that are generated during one or more forward and one or more back strokes of the amplified piezoelectric actuator to generate an average interferogram before the Fourier Transform of the average interferogram is performed.

A memory device can be capable of communicating with the processor. Furthermore, the memory device can be configured to store data, one or more outputs of the processor, and/or software programming.

A display can be configured to display one or more useful outputs. In one embodiment, the outputs include those from the processor and/or the memory device, in which the one or more outputs can include position data from the APA, return assembly, interferograms, Fourier Transform of the interferograms, and/or spectra.

Uses and Methods Thereof

The apparatuses and systems herein can be configured to analyze a sample. In one instance, the apparatus or system is configured to measure spectra of the sample using attenuated total internal reflectance (ATR), diffuse reflectance, or transmission modes of operation. Non-limiting components for such measurements include an ATR crystal, flat mirrors, parabolic mirrors, off-axis parabolic mirrors, lenses, and/or windows.

The present disclosure also encompasses method of using such apparatuses or systems for the analysis of samples. In one embodiment, the method of analyzing a sample includes providing a sample in an optical path of a beam (e.g., a combined beam from a beamsplitter, as described herein) from an interferometer (e.g., any described herein). The method can further include moving at least one optical component (e.g., a reflector) of the interferometer by using an APA that is directly or indirectly coupled to at least one optical component. In some embodiments, a position of at least one optical component is determined by the APA.

In further embodiments, the method includes obtaining an interferogram of the sample from the interferometer (e.g., by using a detector of the interferometer to measure data for spectra, using a processor to generate the spectra based on the data, and using a display to show the generated spectra) and optionally processing the interferogram by way of Fourier Transform analysis (e.g., by using memory devices configured to store programs for conducting such analysis and using a processor configured to execute such programs).

The method can include any further steps to activate, actuate, or otherwise employ any component herein to move at least one optical component. For instance, if the interferometer includes a return assembly, then the method can include moving at least one optical component (e.g., a reflector) in a forward stroke by using an APA and then employing the return assembly to move at least one optical component in a back stroke.

### Example 1: Non-Limiting Michelson Interferometer

FIG. 5 provides a non-limiting Michelson interferometer, which includes a thermal emission light source 505 having an associated parabolic reflector, which projects culminated light on to a plate beamsplitter 508. The light shown on the plate beamsplitter 508 is divided into two orthogonal beams: a first beam and a second beam. One of the beams leaves the beamsplitter 508 at 900 to the incoming beam and is directed towards a moving corner cube retroreflector 502. This first beam is reflected back towards the beamsplitter 508 by the moving corner cube retroreflector 502.

The second beam passes through the beamsplitter 508 and then proceeds after a slight shift in the same direction as the original beam through a compensator plate 509 and from there to a stationary corner cube retroreflector 503. The second beam is reflected off of the stationary corner cube retroreflector 503 and back along the same path to the beamsplitter 508, where it is then reflected at 90° to the incoming beam. On exiting the beamsplitter 508, the first and second beams are recombined to form a single beam. Because the optical path lengths of the first and second beams are different, they form an interference pattern when recombined.

The combined beam proceeds forward striking an off-axis parabolic mirror 504, which focuses the light through a diamond single bounce ATR crystal 510 and from there on to a MCT (Mercury-Cadmium-Telluride) detector 506.

Other components of the interferometer include an amplified piezoelectric actuator 501, which powers and controls the movement of the moving corner cube retroreflector 502. A mounting plate 507 can be included, which mechanically connects the moving corner cube retroreflector 502 to the amplified piezoelectric actuator 501. Compression springs 512 integrated with the mounting plate 507 can be used to provide supplemental force for the back stroke; and a sleeve bearing 511 can be used to guide the linear movement (e.g., along the x-axis and between the beamsplitter 508 and the actuator 501) of the moving corner cube retroreflector 502.

As seen in FIG. 5, the interferometer can be configured to use an amplified piezoelectric actuator 501 to drive a moving corner cube retroreflector 502. This example depicts a system that uses a total internal reflectance (ATR) diamond 510 for obtaining spectra of samples that are pressed against the optical surface of the diamond. Other systems designed for diffuse reflectance and transmission modes of operation are not depicted but are encompassed by embodiments herein.

### Example 2: Further Non-Limiting Michelson Interferometer

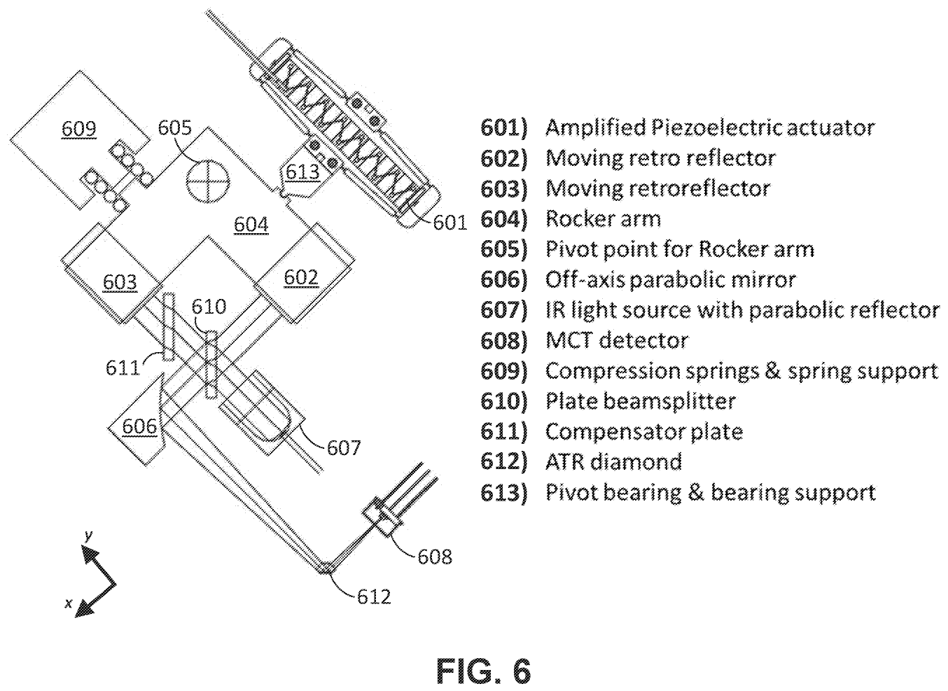

FIG. 6 shows another non-limiting Michelson interferometer including a thermal emission light source 607 having an associated parabolic reflector, which projects culminated light on to a plate beamsplitter 610. The light shown on the plate beamsplitter 610 is divided into two orthogonal beams: a first beam and a second beam. The first beam leaves the beamsplitter 610 at 900 to the incoming beam and is directed towards a moving corner cube retroreflector 602. This first beam is reflected back towards the beamsplitter 610 by the moving corner cube retroreflector 602.

The second beam passes through the beamsplitter 610 and then proceeds after a slight shift in the same direction as the original incoming beam through a compensator plate 611 and from there to a second moving corner cube retroreflector 603. The second beam is reflected off of the corner cube retroreflector 603 and back along the same path to the beamsplitter 610, where it is then reflected at 900 to the incoming beam. On exiting the beamsplitter 610, the first and second beams are recombined to form a single beam. Because the optical path lengths of the first and second beam are different, they form an interference pattern when recombined.

The combined beam proceeds forward striking an off-axis parabolic mirror 606, which focuses the light through a diamond single bounce ATR crystal 612 and from there on to a MCT (Mercury-Cadmium-Telluride) detector 608. The two corner cube retroreflectors, 602 and 603, are attached to a common rocker arm 604, which has a pivot point 605. An amplified piezoelectric actuator 601 powers and controls the movement of the rocker arm 604 and, hence, the movement of the two moving corner cube retroreflectors, 602 and 603. A pivot bearing (or flexure, not shown) with support 613 provides the mechanical linkage between rocker arm 604 and the amplified piezoelectric actuator 601, which powers the forward movement of the rocker arm 604; and a compression spring with support 609 provides the force to power the reverse movement of the rocker arm 604. This second example is capable of achieving significantly greater differences in the optical path lengths between the two light beams within the interferometer, and hence higher spectral resolution.

As seen in FIG. 6, the interferometer can be configured to use an amplified piezoelectric actuator to drive dual moving corner cube retroreflectors. This example depicts a system that uses a total internal reflectance (ATR) diamond 612 for obtaining spectra form samples pressed against the optical surface of the diamond. Other systems designed for diffuse reflectance and transmission modes of operation are not depicted but are encompassed by embodiments herein.

1. An interferometer comprising:
one or more optical components configured to receive and/or transmit light; and
a first amplified piezoelectric actuator directly or indirectly coupled to at least one of the one or more optical components, wherein the first amplified piezoelectric actuator is configured to move the at least one optical component, and wherein a position of the at least one optical component is precisely controlled by the first amplified piezoelectric actuator and the position of the moving at least one optical component is determined by a voltage applied to the first amplified piezoelectric actuator or by a sensing gauge associated with the first amplified piezoelectric actuator.

2. The interferometer of claim 1, wherein the one or more optical components comprise:
an optical source configured to generate light;
a first reflector;
a second reflector;
a beamsplitter configured to receive the light, to split the light into a first beam directed to the first reflector and into a second beam directed to the second reflector, and to receive the first and second beams transmitted from the first and second reflectors, thereby providing a combined beam, wherein the first amplified piezoelectric actuator is directly or indirectly coupled to the second reflector, and wherein the first amplified piezoelectric actuator is configured to translate the second reflector away from or towards the beamsplitter; and
a target configured to receive the combined beam from the beamsplitter.

3. The interferometer of claim 2, wherein the first amplified piezoelectric actuator comprises an amplified piezoelectric actuator configured to provide a translational movement of the second reflector from about 0.3 mm to about 5 mm.

4. The interferometer of claim 2, wherein the first amplified piezoelectric actuator is configured for operation in an open-loop manner, and optionally wherein the interferometer further comprises: a low noise circuit configured to provide one or more output voltages to drive the first amplified piezoelectric actuator, wherein the one or more output voltages are configured to provide a position of the second reflector.

5. The interferometer of claim 2, wherein the first amplified piezoelectric actuator is configured for operation in a closed-looped manner, and optionally wherein the interferometer further comprises: a sensing gauge configured to determine a position of the second reflector, wherein the sensing gauge is configured to be associated with the amplified piezoelectric actuator; and a circuit configured to employ a signal from the sensing gauge as an input signal for the circuit.

6. The interferometer of claim 2, further comprising:
a controller coupled to the first amplified piezoelectric actuator, wherein the controller is configured to directly or indirectly transmit a driving signal (e.g., a driving voltage) to the first amplified piezoelectric actuator and to optionally receive a signal from a sensing gauge, and optionally wherein the controller is configured to power and control the first amplified piezoelectric actuator.

7. The interferometer of claim 2, further comprising:
a return assembly configured to provide a supplemental pull force for the second reflector.

8. The interferometer of claim 7, wherein the first amplified piezoelectric actuator is configured to translate the second reflector away from and towards the beamsplitter, and wherein the return assembly is configured to translate the second reflector away from the beamsplitter.

9. The interferometer of claim 7, wherein the return assembly comprises a spring coupled to the second reflector, and wherein the spring is compressed or stretched upon translating the second reflector by the first amplified piezoelectric actuator in a forward stroke, thereby allowing the spring to provide the supplemental pull force that translates the second reflector in the opposite direction on a back stroke.

10. The interferometer of claim 2, wherein:
the first reflector is stationary; or
the first reflector is moving, wherein the first reflector is directly or indirectly coupled to the first amplified piezoelectric actuator or a second amplified piezoelectric actuator, wherein the first or second amplified piezoelectric actuator is configured to translate the first reflector away from and towards the beamsplitter, and optionally wherein the first reflector moves in a different direction from the second reflector, relative to the beamsplitter.

11. The interferometer of claim 2, further comprising:
one or more guide assemblies configured to align the first reflector and/or the second reflector when translating away from or towards the beamsplitter,
optionally wherein the one or more guide assemblies comprise one or more bearings, sleeve bearings, guide bearings, or magnetic bearings located in proximity to the first or second reflector, and
optionally wherein the one or more guide assemblies are configured to align the first or second reflector along an intended axis of motion that is towards and away from the beamsplitter.

12. The interferometer of claim 2, further comprising:
an arm assembly comprising a surface, a pivot point, and a first outer edge,
wherein the first and second reflectors are attached to the arm assembly,
wherein a portion of the first outer edge of the arm assembly is directly or indirectly coupled to the first amplified piezoelectric actuator with a flexure, bearing, or other, and
wherein the first amplified piezoelectric actuator is configured to move the arm assembly about the pivot point, thereby moving the first and second reflectors, independently, away from or towards the beamsplitter.

13. The interferometer of claim 12, further comprising a return assembly that is directly or indirectly coupled to the arm assembly, wherein the return assembly is configured to provide a force that moves the arm assembly in an opposite direction than a movement provided in a forward stroke by the first amplified piezoelectric actuator, and wherein the force provided by the return assembly occurs after the movement provided by the forward stroke.

14. The interferometer of claim 12, wherein the arm assembly comprises a second outer edge that is perpendicular to the first outer edge, and wherein a portion of the first outer edge or the second outer edge is directly or indirectly coupled to a return assembly configured to provide a force that moves the arm assembly in an opposite direction than a movement provided by the first amplified piezoelectric actuator.

15. The interferometer of claim 12, wherein the arm assembly comprises a first portion and a second portion, wherein the first and second portions extend away from the pivot point, and wherein the first reflector is attached to the first portion and the second reflector is attached to the second portion.

16. The interferometer of claim 2, wherein:
the first reflector and/or the second reflector is independently selected from the group consisting of a mirror, a prism, a retroreflector, a retroreflector mirror, a retroreflector prism, or a corner cube retroreflector; or
wherein the beamsplitter comprises a plate beamsplitter or a cubic beamsplitter; or
wherein the target comprises a detector, a screen, or a camera, and optionally wherein the detector comprises an infrared detector, a mid-infrared detector, or a near-infrared detector.

17. The interferometer of claim 2, further comprising:
a compensating plate in an optical path between the beamsplitter and the first reflector; or
an assembly configured to insert and retract a reference material into and out of an optical path; or
a sample holder configured to provide a sample, wherein the sample holder is further configured to interact the combined light beam with the sample, thereby providing an interacted light beam; wherein the detector is configured to receive the interacted light beam; and optionally wherein the interferometer, the sample holder, and the detector are configured for measuring spectra of the sample using attenuated total internal reflectance (ATR), diffusion reflectance, photoacoustic or transmission mode.

18. The interferometer of claim 2, further comprising one or more of the following:
an ATR crystal substrate or an optically clear sample container or window against which a sample is pressed;
one or more flat mirrors, parabolic mirrors, off-axis parabolic mirrors, lenses, windows, or combinations thereof,
one or more controller systems configured to power and control the optical source, the first amplified piezoelectric actuator, and/or the detector;
one or more positioning systems configured to determine a position of the first reflector and/or the second reflector based on a voltage driving the first amplified piezoelectric actuator and/or based on a signal from a sensing gauge configured to sense a movement and/or a position of the first amplified piezoelectric actuator;
a first converter configured to digitize a signal transmitted from the detector;
a second converter configured to transform a digital signal transmitted from the one or more controller systems into an analog signal for driving the first amplified piezoelectric actuator;
a processor configured to receive one or more signals from the first amplified piezoelectric actuator, one or more sensing gauges, and/or the detector, wherein the processor is optionally configured to record position data from the first amplified piezoelectric actuator, to record a signal from the detector, to generate an interferogram, to correct an interferogram for non-linearity and/or hysteresis between forward and back strokes of the first amplified piezoelectric actuator, to generate an average interferogram, and/or to execute software for system control, data acquisition, data correction, data manipulation, and/or analysis including Fourier Transform of the interferogram to generate spectra;
a memory device capable of communicating with the processor, wherein the memory device is configured to store data, one or more outputs of the processor, and/or software programming; and/or
a display configured to display one or more outputs of the processor and/or the memory device, wherein the one or more outputs can include position data from the first amplified piezoelectric actuator, interferograms, Fourier Transform of the interferograms, and/or spectra.

19. A system comprising:
the interferometer of claim 2;
one or more controller systems configured to power and control the optical source, the first amplified piezoelectric actuator, and/or the detector;
one or more positioning systems configured to determine a position of the first reflector and/or the second reflector based on a voltage driving the first amplified piezoelectric actuator and/or based on a signal from a sensing gauge configured to sense a movement and/or a position of the first amplified piezoelectric actuator;
a first converter configured to digitize a signal transmitted from the detector;
a second converter configured to transform a digital signal transmitted from the one or more controller systems into an analog signal for driving the first amplified piezoelectric actuator;
a processor configured to receive one or more signals from the first amplified piezoelectric actuator, one or more sensing gauges, and/or the detector, wherein the processor is optionally configured to record position data from the first amplified piezoelectric actuator, to record a signal from the detector to generate an interferogram, to correct an interferogram for non-linearity and/or hysteresis between forward and back strokes of the first amplified piezoelectric actuator, to generate an average interferogram, and/or to execute software for system control, data acquisition, data correction, data manipulation, and/or analysis including Fourier Transform of the interferogram to generate spectra;
a memory device capable of communicating with the processor, wherein the memory device is configured to store data, one or more outputs of the processor, and/or software programming; and/or
a display configured to display one or more outputs of the processor and/or the memory device, wherein the one or more outputs can include position data from the first amplified piezoelectric actuator, interferograms, Fourier Transform of the interferograms, and/or spectra.

20. A method of analyzing a sample, the method comprising:
providing a sample in an optical path of a beam from an interferometer;
moving at least one optical component of the interferometer by using a first amplified piezoelectric actuator that is directly or indirectly coupled to the at least one optical component, wherein a position of the at least one optical component is determined by the first amplified piezoelectric actuator; and
obtaining an interferogram of the sample from the interferometer; and
optionally processing the interferogram by way of Fourier Transform analysis.
